(19) United States
(12) Patent Application Publication
(10) Pub. No.: US 2024/0175719 A1
(43) Pub. Date: May 30, 2024

(54) Multipurpose Spacer

(71) Applicant: PMK Mess- und Kommunikationstechnik GmbH, Bad Soden am Taunus (DE)

(72) Inventors: Michael J. Mende, Portland, OR (US); Mark Heimann, Bad Soden am Taunus (DE); Richard Booman, Lake Oswego, OR (US); Michael Engels, Krefeld (DE); Benno Jacobs, Duisburg (DE)

(21) Appl. No.: 18/525,815

(22) Filed: Nov. 30, 2023

Related U.S. Application Data
(60) Provisional application No. 63/429,139, filed on Nov. 30, 2022.

(51) Int. Cl. G01D 3/036; G02B 6/12

(52) U.S. Cl. CPC G01D 3/0365; G02B 6/12; G02B 2006/12135; G02B 2006/12138

(57) ABSTRACT

A multipurpose spacer having a spacer body with a ground lead, an inner electrical connection, and an outer electrical connection. The multipurpose spacer provides grounding, securing, and low thermal conductivity advantages. The multipurpose spacer is mounted and connected in an assembly in high-frequency electronics testing devices. The multipurpose spacer provides a substantial reduction in error signal modulation bandwidth and improved high-frequency performance.

### CROSS REFERENCE TO RELATED APPLICATION

This application claims the benefit of U.S. provisional application No. 63/429,139, filed Nov. 30, 2022, entitled “Thermally Resistant Spacer.” The contents therein are hereby incorporated by reference.

### FIELD OF THE DISCLOSURE

The present disclosure relates to a multipurpose spacer for use in sensitive and specialized electronics testing devices. The multipurpose spacer provides grounding, securing, and low thermal conductivity advantages.

### BACKGROUND OF THE DISCLOSURE

A common problem in the measurement of high-frequency electrical signals with probes is achieving high-quality signal transmission over long distances or through challenging environments. One method of signal transmission is to convert the electrical signals to optical signals and transmit them via optical fiber cables.

Conversion of an analog electrical input signal to an optical output signal can be highly sensitive to the environment. Changes in temperature or electrical fields and mechanical stresses can impact signal quality and the repeatability of the measurement. If signal conversion is conducted in a transient environment, the advantages of optical signal transmission may be overcompensated by introduced signal conversion errors.

More specifically, electrical-to-optical transmitters (“ETO transmitters”) are often used to convert a high-frequency, analog electrical signal into an analog optical output signal. Many ETO transmitters comprise a laser package for signal conversion. The measured electrical signal is fed into a laser diode which modulates the laser output carrying the signal. This laser output is coupled into an optical fiber. The optical fiber transmits an optical representation of the measured analog signal. The optical signal is measured with an internal monitoring photodiode, which enables feedback control circuits.

There are some challenges in this process. ETO transmitters have a limited signal transmission bandwidth. In an ideal application, the entire bandwidth is available for output signal transmission. In real applications, environmental effects can cause electrical, optical, or structural fluctuations in the ETO transmitter, causing an erroneous signal component or error signal which is introduced into the output signal.

One known error source is thermal expansion or contraction of the ETO transmitter. Any temperature change acting on the ETO transmitter may result in a change of output from the laser diode, the optical coupling between laser diode, the internal photodiode, or the output fiber resulting in a corresponding error signal. Another known error source stems from a parasitic transmission line that is formed between the temperature-controlled chamber surrounding outer metal housing. This unterminated transmission line causes resonance that distorts signals.

Traditionally, error signals are eliminated by various signal modulation or correction techniques that are widely used such as filters, pulse code modulation, differential phase shift keying, amplitude shift keying, frequency shift keying, phase shift keying, quadrature amplitude modulation, and wavelength division multiplexing. Some signal modulation techniques have a high bandwidth consumption which means less bandwidth available for the output signal transmission. Other modulation techniques have the advantage of requiring very little bandwidth but come at the cost of poorer output signal quality. Error modulation signal techniques are often cost prohibitive and inefficient due to requiring multiple modulation techniques or devices to mitigate signal distortion.

### SUMMARY OF THE DISCLOSURE

What is needed are apparatuses and assemblies to maintain the ETO transmitter at a substantially constant temperature to reduce or eliminate error signals, to reduce or eliminate the need for signal correction, to increase bandwidth available for output signal transmission, and to simultaneously ground the temperature-controlled chamber to the housing.

An insulating spacer is provided, suitable for electrically grounding a temperature-controlled chamber to a housing or for terminating or tuning a parasitic transmission line formed between a temperature-controlled chamber and a metal housing.

In one embodiment, the multipurpose spacer comprises a spacer body on which a ground lead, an inner electrical connection, and an outer electrical connection are provided. The ground lead is electrically connected to the inner and the outer electrical connections.

In one embodiment, the multipurpose spacer has at least one resonance-mitigating devices in one or more ground leads that are made as a trace on the PCB, or as a ground lead wire, or as a meandered section in which the ground lead is arranged in a narrow meander-type pattern to increase the thermal resistance of the ground lead.

An assembly may be provided which has a spacer according to the disclosure, a housing, a temperature-controlled chamber, and a temperature control device. The spacer holds down the temperature-controlled chamber and fixes it on a TEC stack by compression of the flexible thermal pad between the TEC stack and a temperature controlled chamber.

Method the steps of implementing the spacer include mounting the temperature controlled device to the housing, placing the temperature-controlled chamber on top of the temperature control device, electrically connecting the temperature-controlled chamber to the proximal electrical connections of the spacer, assembling the housing such that it contacts the proximal electrical connections of the spacer, and observing a reduced error signal and improved high-frequency performance.

### BRIEF DESCRIPTION OF THE DRAWINGS

The accompanying drawings illustrate several embodiments of the disclosure. Together with the description, the drawings serve to explain the principles of the disclosure.

FIG. 1A shows a front view of an exemplary spacer.

FIG. 1B shows a back view of an exemplary spacer.

FIG. 1C shows a front view of an exemplary spacer.

FIG. 1D shows a back view of an exemplary spacer.

FIGS. 1E-1G show front views of exemplary spacers.

FIGS. 2A-2C show front cross-sectional views of exemplary assemblies.

FIG. 3 shows a left rear perspective view of an assembly excerpt in a configuration where the upper housing half is removed.

FIG. 4 shows a left front perspective view of an assembly in a configuration where the upper housing half is removed.

FIG. 5 shows a schematic of an exemplary method for operating the assembly.

### REFERENCE NUMERALS OF THE DRAWINGS

1 Spacer
2 Proximal end
3 Distal end
4 Proximal ground lead
5 Distal ground lead
6 Proximal outer electrical connection
7 Distal outer electrical connection
8 Inward-facing edge
9 Outward-facing edge
10 Proximal inner electrical connection
11 Distal inner electrical connection
12 Proximal edge metal contact
13 Distal edge metal contact
14 Proximal meandered section
15 Distal meandered section
16 Proximal resonance-mitigating device
17 Distal resonance-mitigating device
18 Upper proximal mounting surface
19 Lower proximal mounting surface
20 Spacer body
21 Flat bottom edge
22 Front surface
23 Back surface
24 Proximal bottom edge recess
25 Distal bottom edge recess
26 Inward-facing edge recess
27 Inner surface of the housing
28 Upper distal contact surface
29 Lower distal contact surface
30 Assembly
31 Temperature-controlled chamber
32 Temperature control device
33 Housing
34 Upper housing half
35 Lower housing half
36 Electrical-to-optical transmitter
37 Optical output
38 Fiber-optic cable
39 Insulating volume
40 Flexible thermal pad
41 Base plate
42 Stack spacer
43 Proximal slit
44 Distal slit
45 Proximal lateral gap
46 Distal lateral gap
47 Proximal housing screw
48 Distal housing screw
49 Input buffer PCB
50 Input interface
51 Temperature sensor
52 Probe tip connector
53 Mounting step
54 Placing the flexible thermal pad step
55 Placing step
56 Electrically connecting step
57 Assembling step
58 Observing step

### DETAILED DESCRIPTION

The present disclosure generally provides for multipurpose spacers that comprise a grounding lead and which are suitable for electrically grounding a temperature-controlled chamber to a housing or for terminating or tuning a parasitic transmission line formed between a temperature-controlled chamber and a metal housing. Such a multipurpose spacer may comprise a spacer body on which a ground lead, an inner electrical connection, and an outer electrical connection are provided. The ground lead may be configured to electrically connect the inner and outer electrical connections. One or more connection points may be implemented to properly terminate/tune the parasitic transmission line formed between the temperature-controlled chamber and the metal housing.

The term “grounding” means electrically connecting the temperature-controlled chamber to the housing via the ground lead over the resistors. The housing then acts as a reference or reference potential plane. A low impedance path between the temperature-controlled chamber and the housing is established.

The term “terminating” means termination or tuning of a parasitic transmission line formed between the temperature-controlled chamber and a metal housing.

Providing the multipurpose spacer to ground the temperature controlled chamber improves the frequency characteristic of the high-frequency electrical signal. The signal quality is improved, and the error signal is reduced. The need for error signal correction is reduced and a higher fraction of the total bandwidth is available for output signal transmission. Output signal refers to the optical output signal representing the measured electrical input signal.

The spacer may have a multi-purpose role. It may be the carrier structure for the ground lead, the inner, and the outer electrical connections. It may also provide support for the temperature-controlled chamber when assembled in an assembly according to the present disclosure. It may further provide a high thermal resistance between the temperature-controlled chamber and the housing.

The structural integration of a ground lead inherently creates an electrical connection/termination between the temperature-controlled chamber and the housing and, as a side-effect, a low thermal resistance bridge. Such a thermal bridge may reduce the temperature-controlled chamber's ability to maintain the ETO transmitter at a uniform temperature. This may cause increased error signals in case of temperature changes and increased power consumption for the TEC. To minimize the effects of the multipurpose spacer, the spacer may be made from a thin PCB material. To avoid thermal loss over the ground lead, the traces on the arc may be realized as narrow as possible. Additionally, the length of each trace can be increased by meandering.

The benefits of the added ground lead can be harnessed with negligible impact on the chamber's ability to maintain the electrical-to-optical transmitter at a uniform temperature. This leads to an increase in signal quality and a reduced error signal. A reduced need for error signal modulation is achieved and a bigger fraction of the total bandwidth may be used for output signal transmission.

A resonance mitigation device, for example a resistor, arranged in the ground lead, may lead to fewer resonances caused by the ground lead at high-frequencies by properly terminating/tuning the parasitic transmission line formed between the between the temperature-controlled chamber and the metal housing.

The ground lead, like any conductor, has a certain impedance. The ground impedance will cause a certain voltage to form between the temperature-controlled chamber and the housing, which may cause grounding interference, or resonances. With the resonance mitigation device, such resonances can be avoided or at least reduced.

Without such resonances, output signal quality can be improved, and the error signal is reduced. Hence, the need for error signal modulation can be reduced and a bigger fraction of the total bandwidth may be used for output signal transmission.

In the following sections, detailed descriptions of examples and methods of the disclosure will be given. The description of both preferred and alternative examples is exemplary only, and it is understood that to those skilled in the art that variations, modifications, and alterations may be apparent. It is therefore to be understood that the examples do not limit the broadness of the aspects of the underlying disclosure as defined by the claims.

### Detailed Descriptions of the Drawings

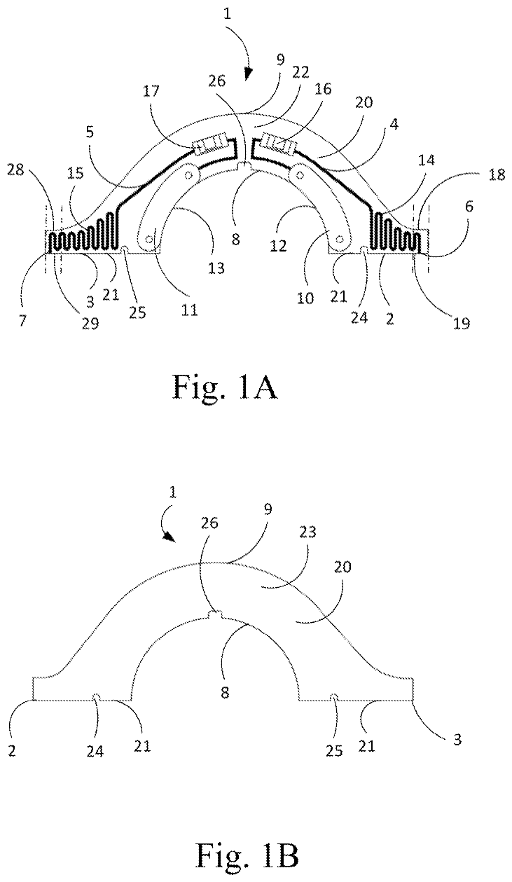

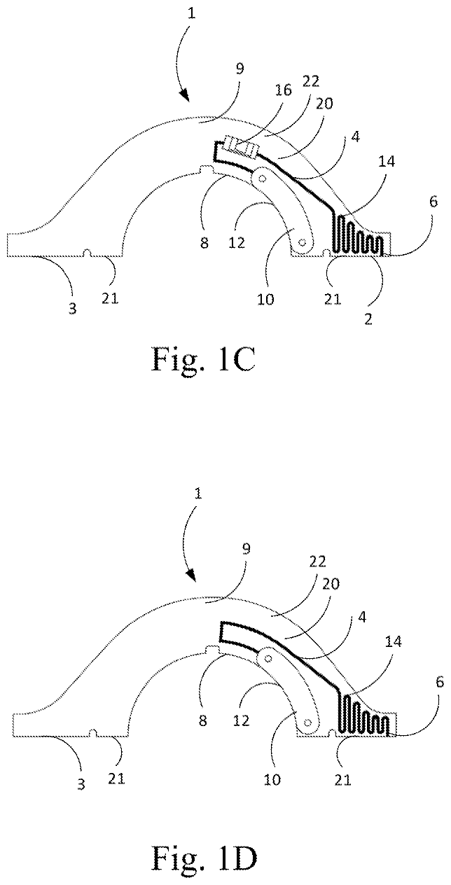

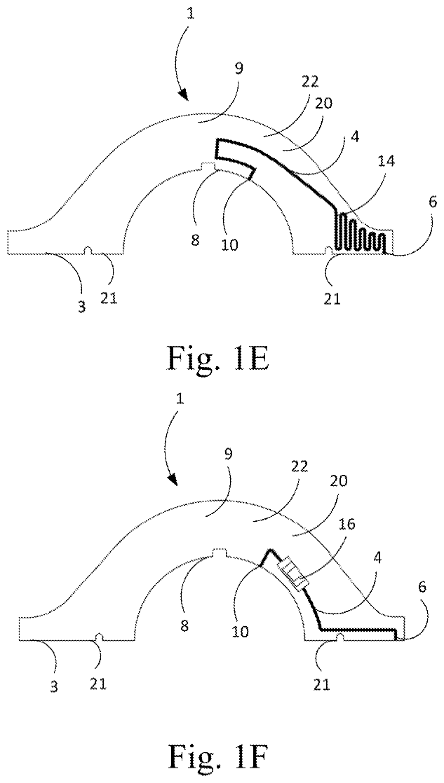

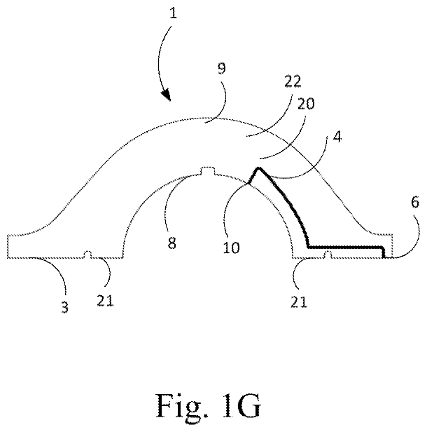

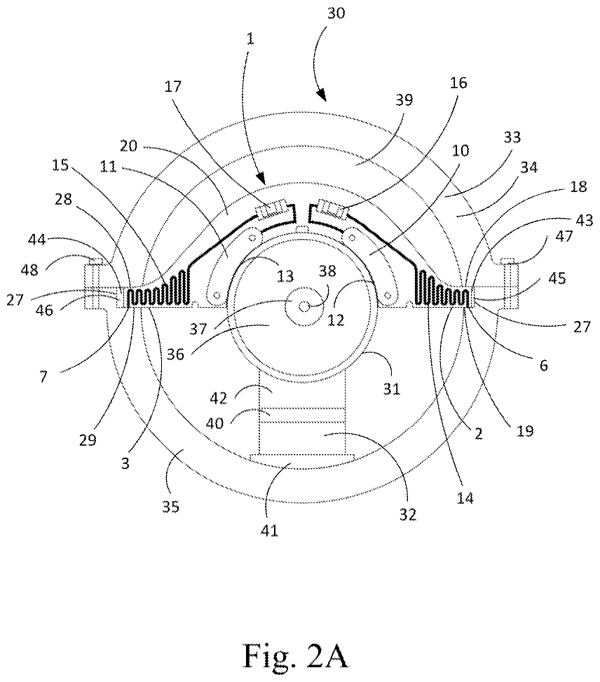

Referring to FIG. 1, a front view of an exemplary spacer shown. The spacer 1 may comprise a spacer body 20 having a proximal end 2, a distal end 3, and a front surface 22. In the shown illustration, “proximal” refers to the right lateral end and “distal” refers to the left lateral end of the spacer 1.

According to some embodiments, the spacer body 20 may for example comprise a printed circuit board, (“PCB”) material. The PCB material may be a single layer, double layer, multiple layer board. The spacer body may comprise a PCB material having a thickness ranging from approximately 0.1 mm to approximately 1 mm. Preferred embodiments have a thickness of 0.5 mm, 0.4 mm, 0.3 mm or 0.2 mm. The spacer body 20 may comprise a proximal ground lead 4 and a distal ground lead 5. According to this exemplary embodiment, the spacer 1 can be electrically grounded to a housing on its proximal and its distal ends. The proximal ground lead 4 and distal ground leads 5 may be provided in the shape of wires, traces, or leads printed to the spacer body 20, which may comprise a printed circuit board configuration. The proximal ground lead 4 and the distal ground lead 5 may be provided substantially symmetrically on their respective proximal and distal side of the spacer. According to the exemplary embodiment shown in FIG. 1, the proximal ground lead 4 and the distal ground lead 5 may be provided slightly asymmetrically in order to account for mechanical or spatial constraints.

On its proximal end 2, the spacer 1 may comprise a proximal outer electrical connection 6, which may be configured for attachment to an adjacent housing. Likewise, the spacer 1 may comprise a distal outer electrical connection 7 on its distal end 3. The distal outer electrical connections 6, 7 may be configured such that they achieve a minimum total contact surface between connectors and spacer, while still providing an electrical connection. Ideally, the contact surfaces of the spacer are on its top and bottom surfaces on the outside end of the spacer.

To achieve this, the proximal outer electrical connection 6 and the distal outer electrical connection 7 may configured for being inserted into a slit of a housing. The proximal ground lead 4 may be configured to provide an electrical contact at the proximal end 2 and at the flat bottom edge 21 of the spacer. The distal ground lead 5 may also be configured to provide an electrical contact at the distal end 3 and the flat bottom edge 21 of the spacer 1. This configuration allows an electrical contact to a housing.

The spacer 1 may comprise an upper proximal contact surface 18, a lower proximal contact surface 19, an upper distal contact surface 28, and a lower distal contact surface 29. These contact surfaces may be configured to be the sole contact surfaces at which the spacer 1 may be held in place when assembled in a housing. With this configuration, the spacer 1 can be held in place while exposing a minimum contact surface to the housing, thereby minimizing conductive heat transport between housing and spacer 1. The proximal outer electrical contact 6 and the distal outer electrical contact 7 are designed such that an electrical contact is provided on the lower proximal contact surface 19 and the lower distal contact surface 29, respectively.

With this configuration, several advantages are achieved. First, electrical grounding of the temperature-controlled chamber 31 is possible. Second, holding the spacer in place by a vertical clamping force is possible, allowing the provision of lateral gaps for thermal expansion compensation. Third, the cross-section for conductive heat transport between housing and spacer is minimal.

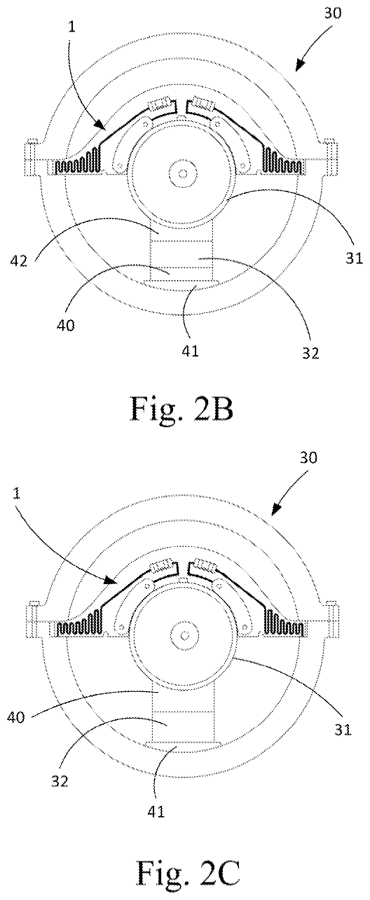

The body 20 of the spacer 1 may be a thin plate, for example made of resin, and may comprise a flat bottom edge 21 and an arc-shaped top edge 9. The arc-shaped top edge 9 may have a transition that tapers laterally such as to form thin left and right handle-like structures. According to the illustration provided in FIG. 1, the right structure constitutes the proximal end 2 and the left structure constitutes the distal end 3. Along its bottom edge 21, the spacer body 20 may have a cut-out in the shape of a semi-circle, which is the inward-facing edge 8, a proximal bottom edge recess 24, and a distal bottom edge recess 25. The inward-facing edge 9 is configured to provide an abutment for the temperature-controlled device as shown in FIG. 2 and may comprise an inward-facing edge recess 26. The proximal bottom edge recess 24, the distal bottom edge recess 25, and the inward-facing edge recess 26 may be used as guiding openings for wires or sensors. For example, said recesses may be used to lead through the wires connected to temperature sensors.

The proximal ground lead 4 may electrically connect the proximal end 2 of the spacer 1 with the inward-facing edge 8. Likewise, the distal ground lead 5 may electrically connect the distal end 3 of the spacer 1 with the inward-facing edge 8. Along the inward-facing edge 8, the spacer 1 may comprise a proximal inner electrical connection 10, suitable for connecting the proximal ground lead 4 to a temperature-controlled device to be mounted to the inward-facing edge 8. The spacer 1 may further comprise a distal inner electrical connection 11, suitable for connecting the distal ground lead 5 to a temperature-controlled device to be mounted to the inward-facing edge 8. On the proximal side along the inward-facing edge 8, electrical connection of the spacer 1 may be achieved along the proximal edge metal contact 12. On the distal side along the inward-facing edge 8, electrical connection of the spacer 1 may be achieved along a distal edge metal contact 13.

The proximal inner electrical connection 10 and the distal inner electrical connection 11, may have a substantially kidney-shaped form, wherein their inward-facing proximal edge metal contact 12 and the distal edge metal contact 13 may follow the shape of the inward-facing edge 8 of the spacer 1.

The proximal ground lead 4 may comprise a proximal resonance-mitigating device 16, arranged in the electrical communication between the proximal outer electrical connection 6 and the proximal inner electrical connection 10. Likewise, the distal ground lead 5 may comprise a distal resonance-mitigating device 17, arranged in the electrical communication between the distal outer electrical connection 7 and the distal inner electrical connection 11. The proximal and distal resonance-mitigating devices 16, 17 may be configured to mitigate high-frequency-induced resonances. For example, the resonance-mitigating devices 16 and 17 may be resistors.

The proximal ground lead 4 may further comprise a proximal meandered section 14, along which the proximal ground lead 4 is arranged on the spacer body 20 in a meander-shaped pattern or a narrow meander-type configuration such as a vertical or horizontal woven lines or concentric lines. The proximal meandered section 14 may be provided between the proximal outer electrical connection 6 and the proximal resonance-mitigating device 16. Likewise, the distal ground lead 5 may comprise a distal meandered section 15, along which the distal ground lead 5 is arranged on the spacer body 20 in a meander-shaped pattern. The distal meandered section 15 may be provided between the distal outer electrical connection 7 and the distal resonance-mitigating device 17. With a meandered section, the length of the ground lead may be increased. This has the benefit of reducing the heat transfer from the proximal electrical connection to the proximal inner electrical connections, or vice versa, via the proximal ground lead 4. The same applies to the distal ground lead 5 and the distal meandered section 15. The lower the heat transport via a ground lead 4, 5 and the spacer 1 itself, the higher the thermal resistance between the temperature-controlled chamber and the housing. The higher this thermal resistance, the more uniform and constant the temperature distribution on the temperature-controlled chamber, and the lower the error signal. A lower error signal requires less bandwidth allocation for error signal modulation and leaves more bandwidth available for output signal transmission.

In exemplary embodiments, the spacer may comprise a ground lead. The spacer may comprise two ground leads, each comprising a proximal electrical connection and a distal electrical connection. The proximal electrical connections may be electrically connectable to the temperature-controlled chamber. The distal electrical connections may be electrically connectable in the housing.

Each ground lead may further comprise a resonance mitigation device, for example, a resistor. The two ground leads may be provided substantially symmetrically on either side of the spacer. The two ground leads may also be provided slightly asymmetry due to mechanical constraints. Each ground lead having an electrical pathway extending from the proximal electrical connection via the resonance mitigating device to the proximal electrical connection. The ground lead may comprise a ground lead wire establishing the electrical pathway. The spacer is thus grounded to the housing on both sides.

Referring now to FIG. 1B, a back view of an exemplary spacer is shown. The spacer body 20 of the spacer 1 may have a smooth back surface 23. All grounding components may be provided on the opposite side. Alternatively, some, additional, or redundant grounding components may be provided on the back surface 23.

Referring now to FIG. 1C, a front view of an exemplary spacer is shown. According to this embodiment, the spacer 1 may comprise only proximal components for grounding the spacer 1 against the housing. Hence, a temperature-controlled device mounted to the inward-facing edge 8 of the spacer 1 can be grounded to a housing only via the proximal ground lead 4 and its electrical components. In an alternative embodiment, the spacer 1 may comprise only distal grounding components. The back view of the spacer according to this embodiment may be identical to the back view shown in FIG. 1B.

Referring now to FIG. 1D, a front view of an exemplary spacer is shown. According to this embodiment, the spacer 1 may comprise only proximal grounding components for grounding the spacer 1 against a housing. The spacer 1 of this embodiment may not comprise a resonance-mitigating device. In an alternative embodiment, the spacer 1 may have a similar configuration, but on the distal side instead of the proximal side. The back view of the spacer according to this embodiment may be identical to the back view shown in FIG. 1B.

Referring now to FIG. 1E, a front view of an exemplary spacer is shown. According to this embodiment, the spacer 1 may comprise only proximal grounding components for grounding the spacer 1 against a housing. The proximal inner electrical connection 10 of this embodiment may be provided by the proximal ground lead 4 extending to the inner electrical edge 8 of the spacer body 20. In an alternative embodiment, the spacer 1 may have a similar configuration, but on the distal side instead of the proximal side. The back view of the spacer according to this embodiment may be identical to the back view shown in FIG. 1B.

Referring now to FIG. 1F, a front view of an exemplary spacer is shown. According to this embodiment, the spacer 1 may comprise only proximal grounding components for grounding the spacer 1 against a housing. The proximal ground lead 4 may not comprise a meandered section. In an alternative embodiment, the spacer 1 may have a similar configuration, but on the distal side instead of the proximal side. The back view of the spacer according to this embodiment may be identical to the back view shown in FIG. 1B.

Referring now to FIG. 1G, a front view of an exemplary spacer is shown. According to this embodiment, the spacer 1 may comprise only proximal grounding components for grounding the spacer 1 against a housing. The ground lead 4 may not comprise any additional components. Instead, it may electrically connect the inward-facing edge 8 directly to the proximal end 2 of the spacer. In an alternative embodiment, the spacer 1 may have a similar configuration, mirrored to the distal side. The back view of the spacer according to this embodiment may be identical to the back view shown in FIG. 1B.

Referring now to FIG. 2A, a front cross-sectional view of an exemplary assembly is shown. The assembly 30 comprises the spacer 1, a temperature-controlled chamber 31, a temperature control device 32, and a housing 33, comprising an upper housing half 34 and a lower housing half 35. The temperature control device 32 may by a Thermo-Electric-Cooler (“TEC”). The temperature control device 32 may be provided in a stack configuration, comprising a base plate 41, the temperature control device 32, a flexible thermal pad 40, and a stack spacer 42. In the embodiment shown in FIG. 2A, the base plate 41 is connected to the inside of the lower housing half 35 and the stack spacer 42 is connected to the temperature-controlled chamber 31. The flexible thermal pad 40 is provided between the temperature-control device 32 and the stack spacer 42. The stack spacer 42 may comprise or consist of a material of a high heat conductivity. According to this embodiment, the stack comprises the following sequence, from bottom to top: base plate 41, temperature control device 32, flexible thermal pad 40, and stack spacer 42.

The temperature-controlled chamber 31 may have the shape of a cylindrical tube. In a preferred embodiment, the temperature-controlled chamber 31 may have the shape of a cylindrical tube with a flat extension to thermally connect to the temperature control device over the flexible thermal pad 40.

The spacer 1 is shown according to the embodiment disclosed in FIG. 1A but could be any of the disclosed spacers. The temperature-controlled chamber 31 may house an electrical-to-optical transmitter 36 on its inside. The electrical-to-optical transmitter 36 may comprise an optical output 37 comprising a fiber optical cable 38, through which a converted, optical signal may be guided out of the electrical-to-optical transmitter 36 and, eventually, out of the housing 33.

The housing 33 may be an electrically conducting housing suitable for connecting a ground lead 4, 5 to an inner surface 27 of the housing. For example, the housing 33 may comprise an aluminum body with a nickel plating on its inner surface 27. The top of the temperature control device 32 may be the heating, cooling, or heating and cooling end of a thermo-electric cooler. The temperature-controlled chamber 31 may comprise the electrical-to-optical transmitter 36 on its inside. Electrically connecting the temperature-controlled chamber 31 to the inner electrical connections 10, 11 of the spacer 1 may be achieved by soldering.

The temperature-controlled chamber 31 may be supported by the temperature control device 32 and by the spacer 1 in such a way that the temperature-controlled chamber 36 rests essentially in the center of the housing 33 and is surrounded by an insulating volume 39. The insulating volume 39 may be air or may comprise a thermally and electrically insulating material. Alternatively, the insulating volume 39 may be air or may comprise a thermally or electrically insulating material.

The sensitive signal conversion happens within the electrical-to-optical signal transmitter 36 inside the temperature-controlled chamber 31. To achieve a high-quality optical output signal that is repeatable throughout a wide range of assembly operation conditions, the electrical-to-optical output transmitter 36 must be kept at steady-state conditions.

During operation, the assembly 30 may be exposed to various steady-state and transient energy fluxes, for example external heat fluxes and electromagnetic fields or currents. With the assembly according to the present disclosure, the electrical-to-optical transmitter 36 can be shielded efficiently from such energy fluxes.

Pertaining to heat fluxes, the assembly 30 comprises active and passive heat insulation technologies. ‘Active heat insulation’ is provided by the temperature-control device 32. Temperature changes within the electrical-to-optical transmitter 36 can be measured and countered with appropriate control of the temperature-control device 32. ‘Passive heat insulation’ is provided by suspending the entire temperature-controlled chamber 31 inside the insulating volume 39. This reduces conductive heat transport to a minimum. Although far less problematic, radiation heat transport phenomena are also mitigated by suspending the temperature-controlled chamber 32 essentially concentrically inside the insulating volume 39.

The temperature-controlled chamber 31 may have only four connections that constitute ‘heat bridges’, via which conductive heat fluxes may reach the temperature-controlled chamber 31, namely i) the temperature control device 32, b) the spacer 1, c) input connections, and d) output connections, such as the fiber optic cable. These four connections are essential for operation and holding the temperature-controlled device 31 in place.

Conductive heat transport via the temperature-control device 32 is negligible, since this device is temperature controlled itself. Conductive heat transport via the spacer 1 is minimized by a minimal contact surface where the spacer 1 is mounted to the housing 33. In the shown embodiment, the spacer 1 may be mounted to the housing 33 by inserting its proximal end 2 in a proximal slit 43 of the lower housing half 35 and by inserting its distal end 3 in a distal slit 44 of the lower housing half 35. The proximal slit 43 may be configured such that a proximal lateral gap 45 is provided inside the proximal slit 43, between the proximal end 2 of the spacer 1 and an adjacent wall 27 of lower housing half 35, when the assembly 30 is in an assembled configuration. Likewise, the distal slit 44 may be configured such that a distal lateral gap 46 is provided inside the distal slit 44, between the distal end 3 of the spacer 1 and an adjacent wall 27 of the lower housing half 35, when the assembly 30 is in an assembled configuration. The proximal lateral gap 45 and the distal lateral gap 46 provide a compensation volume for thermal expansion of the housing 33. As a consequence, heat-induced thermal expansion of the housing 33 will not inflict mechanical stresses into the temperature-controlled chamber 31. This prevents changes in signal conversion due to deformation or displacement.

The spacer 1 may be held in place by inserting the proximal end 2 of the spacer into the proximal slit 43, by inserting the distal end 3 of the spacer 1 into the distal slit 44, and by mounting the upper housing half 34 to the lower housing half 35, for example by fastening a proximal housing screw 47 and a distal housing screw 48. The housing screws 47, 48 are schematically illustrated and provided on the outside perimeter of the housing 33. However, these screws may be provided at any other position of the housing if they are suitable for mounting the housing halves.

In an assembled state, the two housing halves 34, 35 fixate the spacer 1 in the slits 43, 44. The spacer body 20 holds down the temperature-controlled chamber 31 and fixes it to the stack of the temperature control device 32, the flexible thermal pad 40, the base plate 41, and the stack spacer 42. A defined compression of the flexible thermal pad 40 is reached, such that the temperature-controlled chamber 31 is safely nested between the spacer 1 and the temperature control device 32 inside the housing 33. A thermally and electrically insulating material may be provided in the insulating volume 39 between the temperature-controlled chamber 31 and the housing 33. With this approach, mounting the housing halves 34, 35 applies a vertical compression force to the proximal and distal ends 2, 3, of the spacer 1, thereby arresting its position relative to the housing 33. Compressing the temperature-controlled chamber 31 against the flexible thermal pad 40 allows secure fixation of the temperature-controlled chamber 31 even if the housing 33 is thermally expanded by external heat influxes.

In an assembled state, the two housing halves 34, 35 may fixate the spacer 1 only via its upper proximal contact surface 18, its lower proximal contact surface 19, its upper distal contact surface 28, and its lower distal contact surface 29. With this configuration, the total contact surface cross-section is minimal. Consequently, heat conduction between housing 33 and spacer 1 is minimal.

Electromagnetic fluxes or currents impacting the assembly 30 may occur in the shape of high-frequency electromagnetic fields or a parasitic transmission line, formed between the temperature-controlled chamber and the metal housing 33. With the proximal ground lead 4 or the distal ground lead 5, electromagnetic fluxes can be mitigated by grounding the temperature-controlled chamber 31 to the housing 33. Electrical grounding of the spacer 1 may for example be achieved via the lower proximal contact surface 19, where the proximal outer electrical contact 6 contacts the lower housing half 35, and via the lower distal contact surface 29, where to distal outer electrical contact 7 contacts the lower housing half 35. When the temperature-controlled chamber 31 is in electrical communication with the housing 33 via one or more ground leads, the housing may then act as a reference or reference potential plane. Consequently, a low impedance path between the temperature-controlled chamber and the housing 33 is established.

The temperature-controlled chamber 31 may be made of a metal material, for example brass. The temperature-controlled chamber 31 may be temperature controlled via the temperature-control device 32, which may be a thermo-electric cooler. The temperature-control device 32 may be connected to the temperature-controlled chamber 31 via a flexible thermal pad 40. The temperature-control device 32 may be arranged orthogonally to a longitudinal axis of the temperature-controlled chamber 31. The temperature-controlled chamber 31 and the flexible thermal pad 40 may have a square or rectangle cross-section. The flexible thermal pad 40 may be configured to match the cylindrical surface of the temperature-controlled chamber 31 on one side and a flat surface of the temperature-control device 32 on an opposite side of the flexible thermal pad 40.

Referring now to FIG. 2B, a front cross-sectional view of an exemplary assembly is shown. According to this embodiment of the assembly 30, the temperature control device 32 is stacked differently compared to the embodiment of FIG. 2A. In the shown stack, the flexible thermal pad 40 is placed on top of the base plate 41 and the temperature control device is placed on top of the flexible thermal pad 40. The stack spacer 42 is connected to the temperature-controlled chamber 31. According to this embodiment, the stack comprises the following sequence, from bottom to top: base plate 41, flexible thermal pad 40, temperature control device 32, and stack spacer 42.

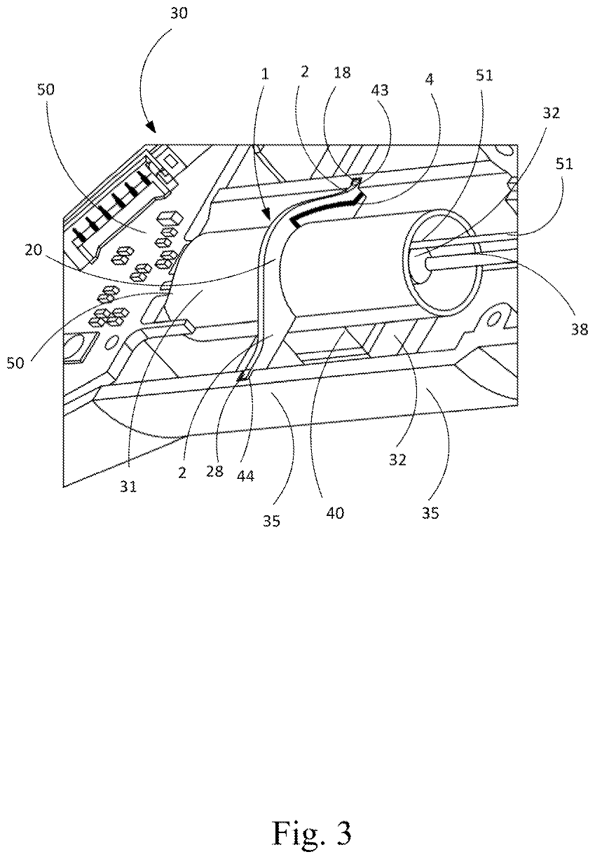

Referring now to FIG. 2C, a front cross-sectional view of an exemplary assembly is shown. According to this embodiment of the assembly 30, the stack spacer is omitted. In the shown stack, the temperature control device is placed directly onto the base plate 41 and the flexible thermal pad 40 is placed on top the temperature control device 32. The flexible thermal pad 40 is connected to the temperature-controlled chamber 31. According to this embodiment, the stack comprises the following sequence, from bottom to top: base plate 41, temperature control device 32, and flexible thermal pad 40. In alternative, preferred embodiments, the base plate 41 may also be omitted. In further preferred embodiments, the position of the flexible thermal pad 40 and the temperature control device 32 may be switched. Referring now to FIG. 3, a left rear perspective view of an assembly excerpt is shown in a configuration where upper housing half is removed. The assembly 30 is shown with a housing 33, represented by the lower housing half 35, a temperature-controlled chamber 31, a temperature control device 32, and a spacer 1. The temperature-controlled chamber 31 may comprise an electrical-to-optical transmitter 36, a temperature sensor 51, and a fiber-optic cable 38. The spacer 1 is shown according to the embodiment disclosed in FIG. 1G but could be any of the disclosed spacers. The spacer 1 is shown inserted in the proximal slit 43 and the distal slit 44 of the lower housing half 35. Inside this lower housing half 35, an input buffer PCB 49 is provided, comprising an input interface 50 for connecting the temperature-controlled chamber 31 thereto.

The task of the temperature control device 32 is to keep an electrical-to-optical transmitter 32 at a constant temperature. Temperature control is achieved by heating or cooling the temperature-controlled chamber 31 via the temperature control device 32, controlled by the temperature sensor 51, which is provided on the inside of the temperature-controlled chamber 31 and thermally connected to the electrical-to-optical transmitter 32. The temperature-controlled chamber 31 may be fixed to the temperature control device 32 via a flexible thermal pad 40. The temperature-controlled chamber 31 may further be connected to the input buffer PCB 49 board by mounting it to the input interface 51 of the input buffer PCB 49.

On the inside of the temperature-controlled chamber 31, an electrical-to-optical transmitter 36 may be arranged, which is indicated in FIG. 2 by the truncated cone inside the temperature-controlled chamber 31. A fiber-optic cable 38 mounted to the electrical-to-optical transmitter 32 extends out of the end of the temperature-controlled chamber 31. This fiber-optic cable 38 carries the converted output signal, converted from an analog high-frequency electrical signal to an analog high-frequency optical signal.

Opposite to the temperature control device on the temperature-controlled chamber 31, the multipurpose spacer 1 may be provided. The shown spacer 1 may be the multipurpose spacer disclosed in FIG. 1. In an embodiment not shown in FIG. 3, multiple such spacers 1 may be used at different locations along the temperature-controlled chamber 31 to improve the termination of the temperature-controlled chamber to the outer metal tube.

In an assembled state, the temperature-controlled chamber 31 is grounded to the housing 33 via the proximal and distal ends 2, 3 of the spacer 1 via the proximal ground lead 4 provided on the spacer body 20.

In an assembled state, the spacer 1 may be held in place by the housing 33 by its upper proximal contact surface 18, its lower proximal contact surface 19 (see FIG. 2), its upper distal contact surface 29, and its lower distal contact surface 29 (see FIG. 2).

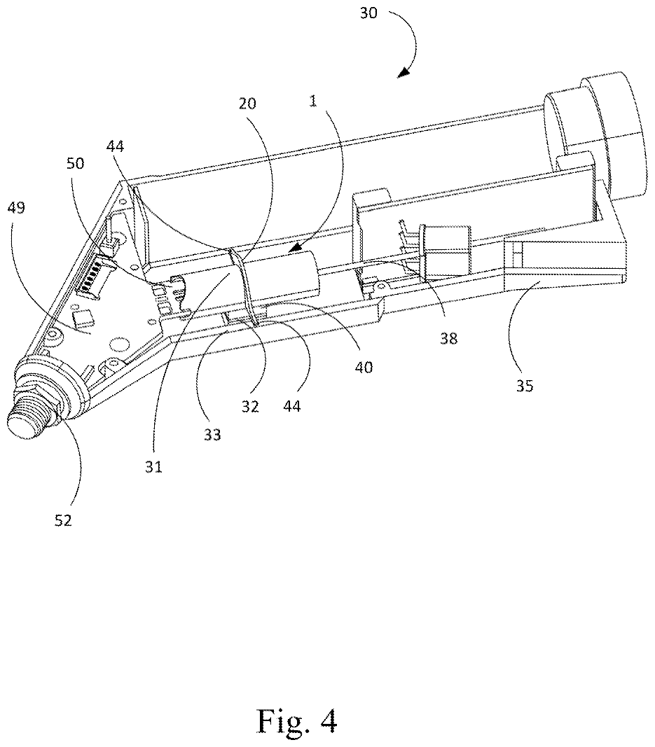

Referring now to FIG. 4, a left front perspective view of an assembly is shown in a configuration where the upper housing half is removed. The assembly 30 shows a probing device, for example a probe head for measuring high-frequency voltage differential signals. The assembly 30 may comprise a probe tip connector 52 suitable for connecting a probe tip for measuring an analog electrical input signal, an input buffer PCB 49 for processing the received analog electrical input signal, a temperature-controlled chamber 31, and an input interface 50 for connecting the temperature-controlled chamber 31 to the input buffer PCB 49.

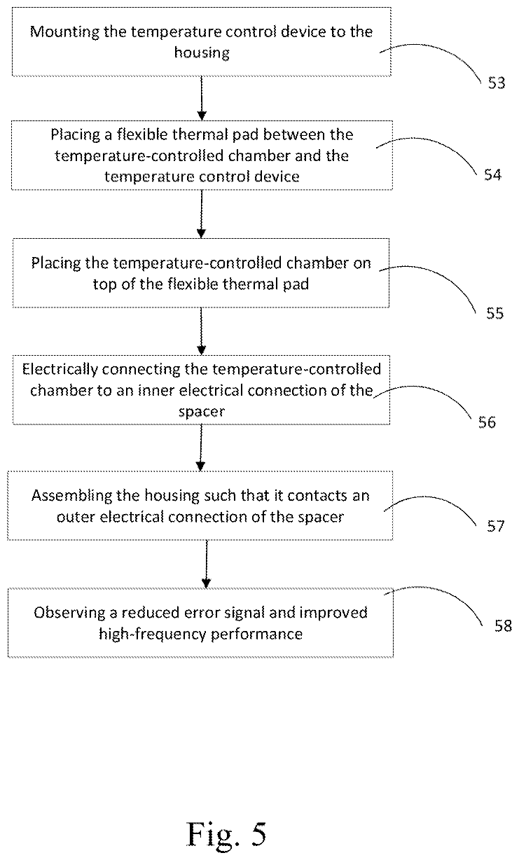

Referring now to FIG. 5, a schematic of an exemplary method for operating the assembly is shown. An exemplary method for operating the assembly according to the present disclosure is shown. The operation method may comprise the steps of mounting 53 the temperature control device to the housing, placing 54 a flexible thermal pad between the temperature-controlled chamber and the temperature control device, placing 55 the temperature-controlled chamber on top of the flexible thermal pad, electrically connecting 56 the temperature-controlled chamber to an inner electrical connection of the spacer, assembling 57 the housing such that it contacts an outer electrical connection of the spacer, and observing 58 a reduced error signal and improved high-frequency performance.

The step of assembling 57 the housing may comprise the step of placing the multipurpose spacer in the slits of the housing and assembling left and right housing halves.

The step of observing a reduced error signal and improved high-frequency performance may include observing an improved optical output signal quality with higher bandwidth.

### Conclusion

Although the disclosure has been described in terms of exemplary embodiments, the disclosure is not limited thereto. This description of the exemplary embodiments is set to be understood in connection with the figures of the accompanying drawings, which are to be considered part of the entire written description. Relative terms such as “lower,” “upper,” “horizontal,” “vertical,” “above,” “below,” “up,” “down,” “top,” “bottom,” “back,” and “front” as well as derivatives such as “horizontally,” “downwardly,” and “upwardly,” should be construed to refer to the orientation as then described or as shown in the particular figure under discussion. These relative terms are for convenience of description and do not require that the spacer or spacer assemblies be constructed or operated in a particular orientation. Terms concerning attachments and coupling such as “connected” refer to a relationship wherein structures are secured or attached to one another either directly or indirectly through intervening structures, as well as both movable or rigid attachments or relationships, unless expressly described otherwise.

While this specification contains many specific implementation details, these details should not be construed as limitations on the scope of any disclosures or of what may be claimed. It should be understood that these exemplary embodiments may be susceptible to various modifications and may present in alternative forms. All statements herein reciting principles, aspects, and embodiments of the disclosure are intended to encompass both the structural and the functional equivalents thereof. Additionally, it is intended that such equivalents include both currently known equivalents and any elements developed in the future that perform the same function regardless of structure. The claims are not intended to be limited to the particular embodiments, modifications, and alternative forms disclosed but are intended to cover all modifications, equivalents, and alternatives falling within the spirit and scope of the disclosure.

What is claimed is:

1. A spacer, comprising a spacer body with an inner surface contacting a temperature-controlled chamber, and an outer surface contacting a housing,
wherein the spacer body comprises an inner electrical connection on the inner surface, an outer electrical connection on the outer surface, and a ground lead electrically connecting the inner electrical connection and outer electrical connection.

2. The spacer of claim 1, further comprising a resonance-mitigating device electrically connected between the inner electrical connection and the outer electrical connection.

3. The spacer of claim 2, wherein the resonance-mitigating device is a resistor.

4. The spacer of claim 1, further comprising a proximal ground lead, a proximal inner electrical connection, a proximal outer electrical connection, a distal ground lead, a distal inner electrical connection, and a distal outer electrical connection.

5. The spacer of claim 1, wherein the spacer body has an arc-shape.

6. The spacer of claim 1, wherein the spacer body comprises a PCB material, and wherein the ground lead comprises PCB traces.

7. The spacer of claim 1, wherein the spacer body has a thickness of about 0.5 mm.

8. The spacer of claim 1, wherein the ground lead comprises a ground lead wire.

9. The spacer of claim 8, wherein the ground lead comprises a meandered section in which the ground lead wire is arranged in a narrow meander-type pattern.

10. An assembly comprising the spacer of claim 1 placed in a housing comprising a temperature-controlled chamber and a temperature control device.

11. The assembly of claim 10, wherein the temperature control device comprises a thermo-electric cooler stack, a temperature sensor, a signal input, and a signal output.

12. The assembly of claim 11, further comprising a flexible thermal pad between the temperature control device and the temperature-controlled chamber.

13. The assembly of claim 11, wherein the housing comprises a slit for receiving an outer portion of the spacer.

14. The assembly of claim 11, wherein the spacer is soldered to the temperature-controlled chamber.

15. The assembly of claim 11, wherein the spacer holds down the temperature-controlled chamber and fixes it on the temperature control device by compression of the flexible thermal pad between the temperature control device and the temperature-controlled chamber.

16. A method for implementing the spacer of claim 1 within a housing, the method steps comprising:
a. Mounting a temperature control device to the housing,
b. Placing a flexible thermal pad between a temperature-controlled chamber and the temperature-control device,
c. Placing the temperature-controlled chamber on top of the flexible thermal pad,
d. Electrically connecting the temperature-controlled chamber to an inner electrical connection of the spacer,
e. Assembling the housing such that it contacts an outer electrical connection of the spacer, and
f. Observing a reduced error signal and improved high-frequency performance.

17. The method of claim 16, further comprising mounting an electrical-to-optical transmitter inside the temperature-controlled chamber and connecting the electrical-to-optical transmitter to an input signal connection and a fiber-optic cable as a signal output.
